(19) United States
(12) Patent Application Publication
(10) Pub. No.: US 2017/0069796 A1
(43) Pub. Date: Mar. 9, 2017

(54) LIGHT EMITTING DEVICE WITH EPITAXIAL STRUCTURE

(71) Applicant: PlayNitride Inc., Tainan City (TW)

(72) Inventors: Tzu-Yang Lin, Tainan City (TW); Yu-Hung Lai, Tainan City (TW); Yu-Yun Lo, Tainan City (TW)

(21) Appl. No.: 15/001,250

(22) Filed: Jan. 20, 2016

(30) Foreign Application Priority Data
Sep. 4, 2015 (TW) 104129262

(51) Int. Cl. H01L 33/40; H01L 27/15; H01L 33/38; H01L 33/62

(52) U.S. Cl. CPC H01L 33/40; H01L 33/62; H01L 27/156; H01L 33/387

(57) ABSTRACT

A light emitting device includes a carrier, at least one epitaxial structure, at least one buffer pad and at least one bonding pad. The epitaxial structure is disposed on the carrier. The buffer pad is disposed between the carrier and the epitaxial structure, wherein the epitaxial structure is temporarily bonded to the carrier by the buffer pad. The bonding pad is disposed on the epitaxial structure, wherein the epitaxial structure is electrically connected to a receiving substrate by the bonding pad.

### CROSS-REFERENCE TO RELATED APPLICATION

This application claims the priority benefit of Taiwan application serial no. 104129262, filed on Sep. 4, 2015. The entirety of the above-mentioned patent application is hereby incorporated by reference herein and made a part of this specification.

### BACKGROUND OF THE INVENTION

Field of the Invention

The invention relates to a semiconductor device, and particularly relates to a light emitting device.

Description of Related Art

In general, a light emitting chip is composed of an epitaxial structure, an N type electrode, and a P type electrode. In addition, the N type electrode and the P type electrode may respectively contact an N type semiconductor layer and a P type semiconductor layer. To make the light emitting chip more applicable, the light emitting chip that is manufactured may be heated for metal bonding to be fixed to a circuit board, so as to form a light emitting module. Due to a mismatch between thermal expansion coefficients of materials of the light emitting chip and the circuit board, a thermal stress and an internal stress that are generated become more and more significant. Thus, there may be dislocation between the epitaxial structure of the light emitting chip and the circuit board, and a structural reliability of the product consequently becomes less desirable.

### SUMMARY OF THE INVENTION

The invention provides a light emitting device suitable to be disposed to various receiving substrates and having a preferable structural reliability.

A light emitting device according to an embodiment of the invention includes a carrier, at least one epitaxial structure, at least one buffer pad, and at least one bonding pad. The epitaxial structure is disposed on the carrier. The buffer pad is disposed between the carrier and the epitaxial structure. In addition, the epitaxial structure is temporarily bonded to the carrier by the buffer pad. The bonding pad is disposed on the epitaxial structure. In addition, the epitaxial structure is electrically connected to a receiving substrate through the bonding pad.

According to an embodiment of the invention, the carrier is a tentative substrate.

According to an embodiment of the invention, the epitaxial structure includes a first type semiconductor layer, an active layer, and a second type semiconductor layer. The active layer is located between the first type semiconductor layer and the second type semiconductor layer. The second type semiconductor layer is located between the active layer and the buffer pad.

According to an embodiment of the invention, a side length of the first type semiconductor layer is smaller than a side length of the second type semiconductor layer, and a difference in side lengths between the first type semiconductor layer and the second type semiconductor layer is in a range from 0.5 micrometers to 5 micrometers.

According to an embodiment of the invention, a thickness of the second type semiconductor layer is greater than a thickness of the first type semiconductor layer.

According to an embodiment of the invention, the thickness of the second type semiconductor layer is 3 times to 15 times of a thickness of the active layer, and the thickness of the second type semiconductor layer is 10 times to 20 times of the thickness of the first type semiconductor layer.

According to an embodiment of the invention, the bonding pad includes at least one first bonding pad and at least one second bonding pad. The first bonding pad and the second bonding pad are located at the same side of the epitaxial structure. The first bonding pad is electrically connected to the first type semiconductor layer, and the second bonding pad is electrically connected to the second type semiconductor layer.

According to an embodiment of the invention, the light emitting device further includes an insulating layer. The insulating layer is disposed on the buffer pad and covers a sidewall of the epitaxial structure. In addition, the insulating layer exposes a top surface of the epitaxial structure to form a contact opening, and the bonding pad is disposed on the contact opening and electrically connected to the epitaxial structure.

According to an embodiment of the invention, an area of an orthogonal projection of the buffer pad on the carrier is 0.6 times to 1.2 times of an area of an orthogonal projection of the epitaxial structure on the carrier.

According to an embodiment of the invention, in a vertical direction with respect to the carrier, the buffer pad and the epitaxial structure are conformal patterns.

According to an embodiment of the invention, a material of the buffer pad includes a polymer.

According to an embodiment of the invention, a highest peak current density of an external quantum efficiency curve of the epitaxial structure is lower than 2 A/cm².

According to an embodiment of the invention, a defect density of the epitaxial structure is less than 5×10⁸/cm².

A light emitting device according to an embodiment of the invention includes a carrier, a plurality of epitaxial structures, a plurality of buffer pads, and a plurality of bonding pads. The epitaxial structures are periodically disposed on the carrier. The buffer pads are disposed between the carrier and the epitaxial structures and respectively disposed in correspondence with the epitaxial structures. In addition, the epitaxial structures are respectively bonded to the carrier by the buffer pads. The bonding pads are disposed on the epitaxial structures. In addition, the epitaxial structures are electrically connected to a receiving substrate through the bonding pads, and a gap between any adjacent two of the buffer pads is 0.2 times to 2 times of a side length of each of the epitaxial structures.

Based on above, since the light emitting device according to the embodiments of the invention has the buffer pad, the buffer pad may absorb the internal stress generated when the light emitting device is disposed on the receiving substrate and the bonding pad is thermally bonded to the receiving substrate, and the movement generated when a high stress is applied to the epitaxial structure is also reduced. In brief, the buffer pad may prevent the dislocation between the epitaxial structure and the receiving substrate. Thus, the structural design of the light emitting device according to the embodiments of the invention helps the subsequent thermal bonding process, and may effectively improve the structural reliability of the light emitting device.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic cross-sectional view illustrating a light emitting device according to an embodiment of the invention.

FIG. 1B is a schematic cross-sectional view illustrating a light emitting device according to another embodiment of the invention.

FIG. 2 is a schematic cross-sectional view illustrating a light emitting device according to another embodiment of the invention.

FIG. 3 is a schematic cross-sectional view illustrating a light emitting device according to another embodiment of the invention.

FIG. 4 is a schematic cross-sectional view illustrating the light emitting device of FIG. 3 being thermally bonded to a receiving substrate.

FIG. 5 is a schematic cross-sectional view illustrating a light emitting device according to another embodiment of the invention.

FIG. 6 is a schematic cross-sectional view illustrating the light emitting device of FIG. 5 being thermally bonded to a receiving substrate.

### DESCRIPTION OF THE EMBODIMENTS

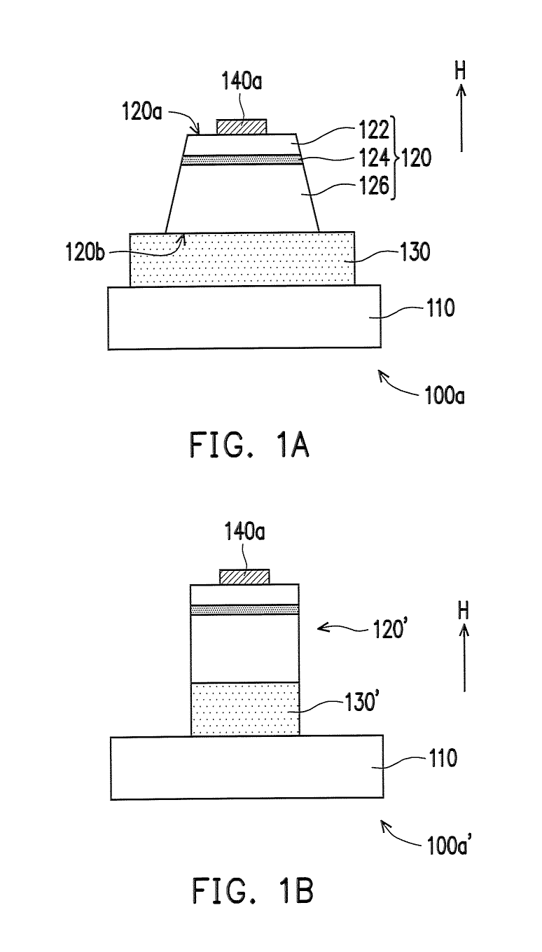

FIG. 1A is a schematic cross-sectional view illustrating a light emitting device according to an embodiment of the invention. Referring to FIG. 1A, in this embodiment, a light emitting device 100a includes a carrier 110, at least one epitaxial structure 120 (FIG. 1A only shows one epitaxial structure), at least one buffer pad 130 (FIG. 1A only shows one buffer pad 130), and at least one bonding pad 140a (FIG. 1A only shows one bonding pad 140a). The epitaxial structure 120 is disposed on the carrier 110. The buffer pad 130 is disposed between the carrier 110 and the epitaxial structure 120, wherein the epitaxial structure 120 is temporarily bonded to the carrier 110 by the buffer pad 130. The bonding pad 140a is disposed on the epitaxial structure 120, wherein the epitaxial structure 120 is electrically connected to a receiving substrate (not shown) through the bonding pad 140a.

Specifically, the carrier 110 of this embodiment is substantially a tentative substrate for temporarily carrying the epitaxial structure 120. In addition, a material of the carrier 110 may include Si, SiC, GaAs, GaN, glass, sapphire, or ceramics, for example. The epitaxial structure 120 includes a first type semiconductor layer 122, an active layer 124, and a second type semiconductor layer 126. In addition, the active layer 124 is located between the first type semiconductor layer 122 and the second type semiconductor layer 126, and the second type semiconductor layer 126 is located between the active layer 124 and the buffer pad 130. In the epitaxial structure 120 of this embodiment, the first type semiconductor layer 122 is a P type semiconductor layer, for example, the second type semiconductor layer 126 is an N type semiconductor layer, for example, and the active layer 124 is a multiple quantum well (MQW) structure. In other embodiments not shown herein, it is also viable that the first type semiconductor layer 122 is an N type semiconductor layer, for example, the second type semiconductor layer 126 is a P type semiconductor layer, for example, and the active layer 124 is a multiple quantum well structure. The invention does not intend to impose a limitation in this regard.

More specifically, the epitaxial structure 120 may include a Group II-VI material (e.g., ZnSe) or a Group III-V nitride material (e.g., GaN, AlN, InN, InGaN, AlGaN, or AlInGaN). In addition, a side length of the epitaxial structure 120 of the embodiment is smaller than the side length of the conventional light emitting diode (e.g., the side length in a range from 0.2 millimeters to 1 millimeter). Preferably, the side length of the epitaxial structure 120 is in a range from 3 micrometers to 40 micrometers. In this embodiment, a bottom surface 120b of the epitaxial structure 120 is wider than a top surface 120a of the epitaxial structure 120, and a cross-sectional side of the epitaxial structure may be deemed as a trapezoid. More specifically, a side length of the first type semiconductor layer 122 is smaller than a side length of the second type semiconductor layer 126, and a difference in side lengths between the first type semiconductor layer 122 and the second type semiconductor layer 126 is in a range from 0.5 micrometers to 5 micrometers. Preferably, the side length of the first type semiconductor layer 122 is in a range from 3 micrometers to 38 micrometers, and the side length of the second type semiconductor layer 126 is in a range from 3.5 micrometers to 40 micrometers. In other embodiments not shown herein, the top surface 120a of the epitaxial structure 120 may also be wider than the bottom surface 120b of the epitaxial structure 120. The cross-sectional side of the epitaxial structure 120 may be deemed as an inverted trapezoid. Namely, the side length of the first type semiconductor layer 122 is greater than the side length of the second type semiconductor layer 126, and the difference in side lengths between the first type semiconductor layer 122 and the second type semiconductor layer 126 is in a range from 0.5 micrometers to 5 micrometers. Preferably, the side length of the first type semiconductor layer 122 is in a range from 3.5 micrometers to 40 micrometers, and the side length of the second type semiconductor layer 126 is in a range from 3 micrometers to 38 micrometers. Furthermore, in yet other embodiments not shown herein, the bottom surface 120b of the epitaxial structure 120 and the top surface 120a of the epitaxial structure 120 may have similar side lengths, and the cross-sectional side of the epitaxial structure 120 may be deemed as a rectangle. Namely, the side length of the first type semiconductor layer 122 and the side length of the second type semiconductor layer 126 are equal. Preferably, the side lengths of the first type semiconductor layer 122 and the second type semiconductor layer 126 are respectively in a range from 3 micrometers to 40 micrometers. Among the three types of embodiments, the design that the bottom surface 120b of the epitaxial structure 120 is wider than the top surface 120a of the epitaxial structure 120 (i.e., the side length of the first type semiconductor layer 122 is smaller than the side length of the second type semiconductor layer 126 and the cross-sectional side of the epitaxial structure 120 is deemed as a trapezoid) is advantageous in having a greater contact area between the epitaxial structure 120 and the buffer pad 130, thus having a desirable stress releasing effect.

As shown in FIG. 1A, in the epitaxial structure 120 of this embodiment, the second type semiconductor layer 126 is close to the buffer pad 130, and the second type semiconductor layer 126 directly contacts the buffer pad 130. Moreover, a thickness of the second type semiconductor layer 126 of this embodiment is greater than a thickness of the first type semiconductor layer 122. In addition, the thickness of the second type semiconductor layer 126 is in a range from 1 micrometer to 6 micrometers, a thickness of the active layer 124 is in a range from 0.1 micrometers to 1 micrometer, and the thickness of the first type semiconductor layer 122 is in a range from 0.1 micrometers to 0.5 micrometers. In an exemplary embodiment, the thickness of the second type semiconductor layer 126 is 5 micrometers, for example, the thickness of the active layer 124 is 0.7 micrometers, for example, and the thickness of the first type semiconductor layer 122 is 0.4 micrometers, for example. Moreover, the second type semiconductor layer 126 in the epitaxial structure 120 has the greatest thickness. The thickness of the second type semiconductor layer 126 is 3 times to 15 times of the thickness of the active layer 124, and the thickness of the second type semiconductor layer 126 is 10 times to 20 times of the thickness of the first type semiconductor layer 122. By having the thickest second type semiconductor layer 126 directly contacting the buffer pad 130, the active layer 124 may be protected to prevent the structure of the active layer 124 from being damaged to thus influence light emitting of the light emitting device 100a.

Moreover, a highest peak current density of an external quantum efficiency curve of the epitaxial structure 120 of this embodiment is smaller than the peak current density of the epitaxial structure of the conventional light emitting diode. Preferably, the highest peak current density of the external quantum efficiency curve of the epitaxial structure 120 of this embodiment is lower than 2 A/cm². More preferably, the highest peak current density of the external quantum efficiency curve of the epitaxial structure 120 of this embodiment is in a range from 0.5 A/cm² to 1.5 A/cm². Namely, the epitaxial structure 120 of this embodiment is suitable to be operated at a low current density. In addition, compared to the epitaxial structure of the conventional light emitting diode, a defect density of the epitaxial structure 120 of this embodiment is also smaller. In general, the defect density of the epitaxial structure of the conventional light emitting diode is approximately in a range from 10⁹/cm² to 10¹⁰/cm², while the defect density of the epitaxial structure 120 of this embodiment is smaller than 5×10⁸/cm², and preferably in a range from 5×10⁵/cm² to 10⁸/cm².

Moreover, the buffer pad 130 of this embodiment may serve as a buffer structure. A material of the buffer pad 130 of this embodiment includes an adhesive polymer, such as epoxy resin, polyimide, polyester, polyurethane, benzocyclobutene, polyethylene, polypropylene, polyacrylate, and a combination thereof, and the buffer pad 130 may be formed through thermal curing or UV curing. In other words, the buffer pad 130 may simultaneously offer adhesive and buffering functions. In an exemplary embodiment, the buffer pad 130 is formed of a polymer through UV curing. As shown in FIG. 1A, a position of the buffer pad 130 and a position of the epitaxial structure 120 in this embodiment correspond to each other. In addition, an area of an orthogonal projection of the buffer pad 130 on the carrier 110 is 0.6 times to 1.2 times of an area of an orthogonal projection of the epitaxial structure 120 on the carrier 110. The buffer pad 130 is structurally designed to ensure that a stress applied to any position of the epitaxial structure 120 may be absorbed by the buffer pad 130. The buffer pad 130 may be a single-layer or multi-layer structure. For example, the buffer pad 130 may be a dual-layer structure formed of two polymer materials or a multi-layer structure formed by alternately stacking two polymer materials. However, the invention is not limited thereto. Besides, as shown in FIGS. 1A and 1B, the epitaxial structures 120 and 120′ may serve as a mask and an etching process may be performed to define shapes and sizes of the buffer pads 130 and 130′. In other words, viewing from a vertical direction H with respect to the carrier 110, the buffer pads 130 and 130′ and the epitaxial structures 120 and 120′ of the light emitting devices 100a and 100a′ of the embodiments are shown as substantially similar patterns. As shown in FIG. 1A, the cross-sectional side of the epitaxial structure 120 that serves as a mask is deemed as a trapezoid. Therefore, the size of the buffer pad 130 defined after the etching process is slightly greater than that of the epitaxial structure 120. As shown in FIG. 1B, the cross-sectional side of the epitaxial structure 120′ serving as a mask is deemed as a rectangle. Therefore, the buffer pad 130′ defined after the etching process is similar to the epitaxial structure 120′. In other embodiments not shown herein, when the cross-sectional side of the epitaxial structure 120 is deemed as an inverted trapezoid, the size of the buffer pad 130 defined after the etching process is slightly smaller than the epitaxial structure 120. More specifically, a relation between the size of the buffer pad 130 and the size of the epitaxial structure 120 may be controlled by adjusting parameters of the etching process.

Besides, the bonding pad 140a of this embodiment is located on the first type semiconductor layer 122 and is structurally and electrically connected to the first type semiconductor layer 122. The epitaxial structure 120 of this embodiment may be electrically connected to the receiving substrate (not shown) through the bonding pad 140a, so as to improve an applicability of the light emitting device 100a. The bonding pad 140a may include one or multiple layers. For example, the bonding pad 140a may include an electrode layer (not shown) and an optionally disposed barrier layer (not shown). The electrode layer may form an ohmic contact with the first type semiconductor layer 122, and a material of the electrode layer may include a high work function metal (e.g., platinum, nickel, titanium, gold, chromium, and a combination thereof) or metal oxide (e.g., indium tin oxide and zinc oxide). The barrier layer may be optionally disposed to prevent impurities from diffusing into the first type semiconductor layer 122. For example, a material of the barrier layer includes, but is not limited to titanium-tungsten alloy, platinum, palladium, titanium, tantalum, and a combination thereof. The bonding pad 140a may further include a reflective layer (not shown) to reflect light emitted by the active layer 124. For example, the reflective layer includes, but is not limited to, silver, aluminum, and an alloy thereof. Furthermore, the bonding pad 140a may also include a non-metal conductive material, such as conductive polymer, graphite, graphene, and black phosphorus. In this embodiment, the bonding pad 140a may be formed of a metal material, a non-metal material, or a combination of metal and non-metal materials, as long as the bonding pad 140a makes the epitaxial structure 120 and the receiving substrate (not shown) electrically connect to each other. When being electrically connected to the receiving substrate, the bonding pad 140a of the light emitting device 100a is aligned and pressed to a pad (not shown) of the receiving substrate through hot pressing. Under a high temperature, a high stress is applied for a period of time for bonding. At this time, the buffer pad 130 of the light emitting device 100a may serve as a buffer to absorb an internal stress generated during bonding, so as to reduce a movement generated when the high stress is applied to the epitaxial structure 120, thereby preventing dislocation between the epitaxial structure 120 and the receiving substrate.

It should be noted that the reference numerals and a part of the contents in the previous embodiment are used in the following embodiments, in which identical reference numerals indicate identical or similar components, and repeated description of the same technical contents is omitted. For a detailed description of the omitted parts, reference can be found in the previous embodiment, and no repeated description is contained in the following embodiments.

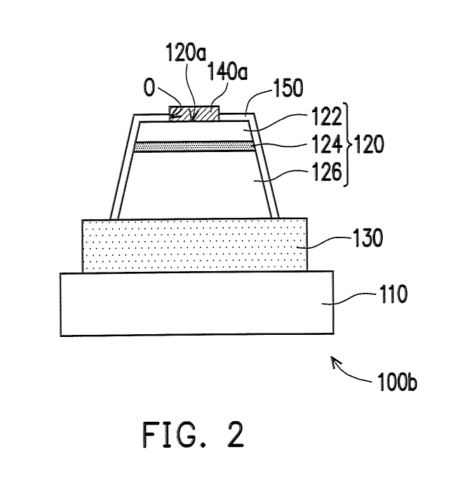

FIG. 2 is a schematic cross-sectional view illustrating a light emitting device according to another embodiment of the invention. Referring to FIGS. 1A and 2 together, a light emitting device 100b of this embodiment is similar to the light emitting device 100a shown in FIG. 1A, except for a difference that the light emitting device 100b of this embodiment further includes an insulating layer 150. The insulating layer 150 is disposed on the buffer pad 130 and covers a sidewall of the epitaxial structure 120, and the insulating layer 150 exposes the top surface 120a of the epitaxial structure 120 to form a contact opening O. A width of the contact opening O is smaller than a width of the top surface 120a of the epitaxial structure 120, and the bonding pad 140a is disposed on the contact opening O and electrically connected to the epitaxial structure 120. In other embodiments not shown herein, the width of the contact opening O may be greater than, close to, or approximately equal to the width of the top surface 120a of the epitaxial structure 120, and the invention is not limited thereto. The insulating layer 150 is disposed to protect an edge of the epitaxial structure 120, so as to prevent the epitaxial structure 120 from moisture and oxygen, and may effectively improve a product reliability of the light emitting device 100b. A material of the insulating layer 150 includes silicon dioxide, aluminum oxide, silicon nitride, and a combination thereof, for example.

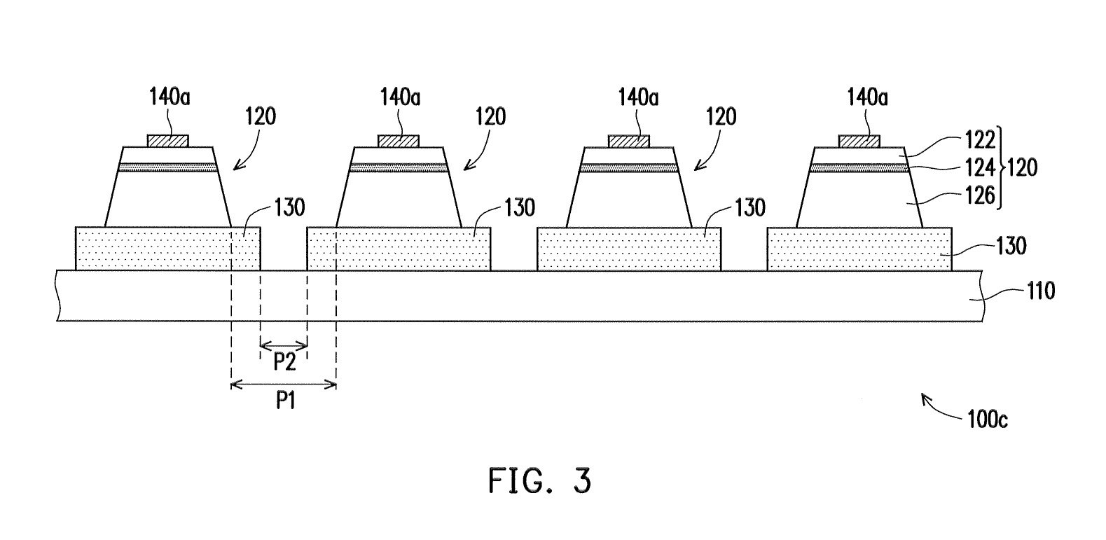

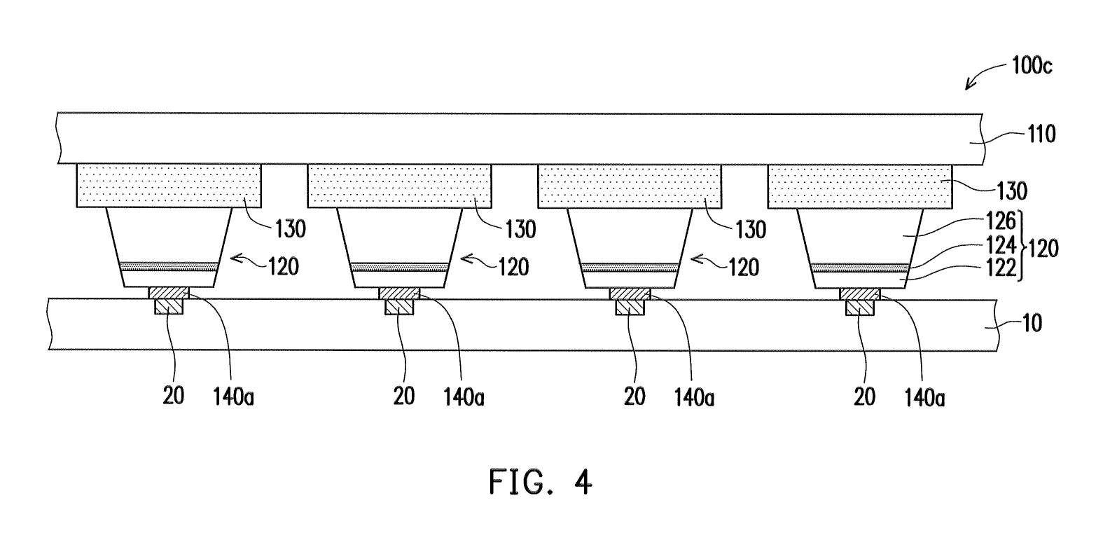

FIG. 3 is a schematic cross-sectional view illustrating a light emitting device according to another embodiment of the invention. Referring to FIGS. 1A and 3 together, a light emitting device 100c of this embodiment is similar to the light emitting device 100a shown in FIG. 1A, except for a main difference that the light emitting device 100c of this embodiment includes a plurality of the epitaxial structures 120 and a plurality of the buffer pads 130. In addition, the epitaxial structures 120 are periodically and separately disposed on the carrier 110, and the buffer pads 130 are respectively disposed in correspondence with the epitaxial structures 120. In an embodiment, the epitaxial structure 120 is in an array arrangement, and a pitch P1 between any adjacent two epitaxial structures 120 is in a range from 2 micrometers to 70 micrometers, and a pitch P2 between any adjacent two buffer pads 130 is in a range from 2 micrometers to 70 micrometers. Regarding subsequent processes, referring to FIG. 4, when the light emitting device 100c is electrically connected to a receiving substrate 10 through a thermal bonding process, the bonding pad 140a may be electrically connected to a pad 20 on the receiving substrate 10. At this time, the buffer pad 130 may absorb the internal stress generated during bonding and reduce the movement generated when the high stress is applied to the epitaxial structure 120. In this embodiment, the receiving substrate 10 may be a display substrate, a lighting substrate, a substrate having transistors or integrated circuits (ICs), or a substrate having metal redistribution lines. More specifically, the pad 20 is formed of a material having a melting temperature lower than 140° C., such as tin or indium. During a thermal bonding process with such design, the receiving substrate 10 is heated to a temperature higher than the melting temperature of the pad 20 and lower than a melting temperature of the bonding pad 140a. At such temperature, the pad 20 is turned into a liquid state, while the bonding pad 140a remains in a solid state, and when the pad 20 and the bonding pad 140a are connected, the liquid-state pad 20 may reduce a collision force at a contact surface, so as to prevent the light emitting device 100c from tilting and assuage imbalance among forces applied to the respective epitaxial structures 120 when bonding.

In this embodiment, the pad 20 is aligned to the receiving substrate 10. However, the invention is not limited thereto. In other embodiments not shown herein, the pad 20 may also be a block protruding from the receiving substrate 10. Namely, an upper surface of the pad 20 is higher than an upper surface of the receiving substrate 10. Alternatively, the pad 20 may also be a block recessed into the receiving substrate 10. Namely, the upper surface of the pad 20 is lower than the upper surface of the substrate 10. Besides, the upper surface of the receiving substrate 10 between the pads 20 may form a light absorption layer (not shown) to absorb a portion of scattered light, so as to reduce a mutual light interference between the epitaxial structures 120.

In this embodiment, the pitch P2 between any adjacent two buffer pads 130 is 0.2 times to 2 times of the side length of the epitaxial structure 120. Preferably, the pitch P2 between any adjacent two buffer pads 130 is smaller than the side length of the epitaxial structure 120, and the pitch P2 between any adjacent two buffer pads 130 is 0.2 times to 0.9 times of the side length of the epitaxial structure 120. If the pitch P2 is smaller than 0.2 times of the side length of the epitaxial structure 120, the buffer pad 130 may expand due to a stress and contact the adjacent buffer pad 130 during the thermal bonding process, thus resulting in a movement of the corresponding epitaxial structure 120. If the pitch P2 is greater than 2 times of the side length of the epitaxial structure 120, a buffer area in the thermal bonding process is not enough, and the epitaxial structure 120 may be damaged easily. In brief, the buffer pad 130 may prevent the dislocation between the epitaxial structure 120 and the receiving substrate 10 and protect the epitaxial structure 120 as well. Thus, the structural design of the light emitting device 100c of this embodiment helps the subsequent thermal bonding process, and may effectively improve a structural reliability of the light emitting device 100c. In addition, since the thickness of the second type semiconductor layer 126 is greater than the thickness of the first type semiconductor layer 122, i.e., the thickness of the first type semiconductor layer 122 is smaller than the thickness of the second type semiconductor layer 126, when the light emitting device 100c is bonded to the receiving substrate 10, the active layer 124 of the epitaxial structure 120 may be closer to the substrate 10, thus resulting in a preferable heat dissipation effect. It should be noted that, after the thermal bonding process, the buffer pad 130 and the carrier 110 may be removed, and another bonding pad (not shown) may be manufactured on the second type semiconductor layer 126 of the epitaxial structure 120. At this time, the epitaxial structure 120, the bonding pad 140a, and the another bonding pad may define a vertically oriented light emitting diode chip.

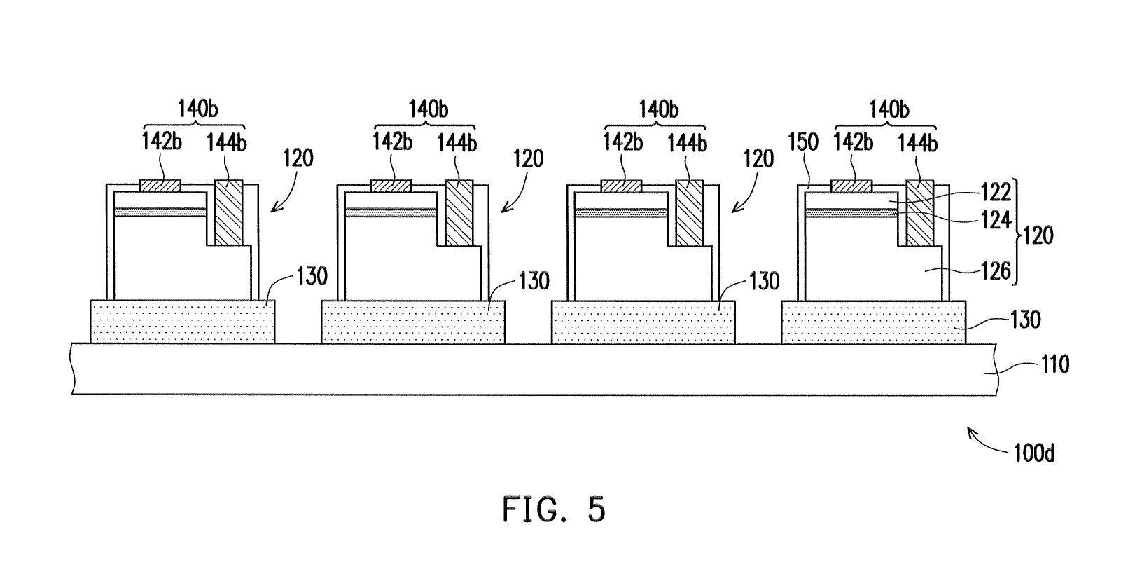

Besides, the invention does not limit the position and the number of the bonding pad 140a. Here, the bonding pad 140a is only disposed on a surface of the epitaxial structure 120 away from the buffer pad 130 and each epitaxial structure 120 is only provided with one bonding pad 140a, However, in other embodiments, referring to FIGS. 3 and 5 together, a light emitting device 100d of this embodiment is similar to the light emitting device 100c shown in FIG. 3, except for a main difference that a bonding pad 140b of the light emitting device 100d of this embodiment includes a first bonding pad 142b and a second bonding pad 144b. The first bonding pad 142b and the second bonding pad 144b are located at the same side of the epitaxial structure 120. In addition, the first bonding pad 142b is electrically connected to the first type semiconductor layer 122, and the second bonding pad 144b is electrically connected to the second type semiconductor layer 126. In other words, each epitaxial structure 120 in this embodiment is provided with a first bonding pad 142b and a second bonding pad 144b, and the first bonding pad 142b and the second bonding pad 144b are located on a surface of the epitaxial structure 120 away from the buffer pad 130. At this time, the design of the epitaxial structure 120, the first bonding pad 142b, and the second bonding pad 144b may be considered as a horizontally oriented light emitting diode chip.

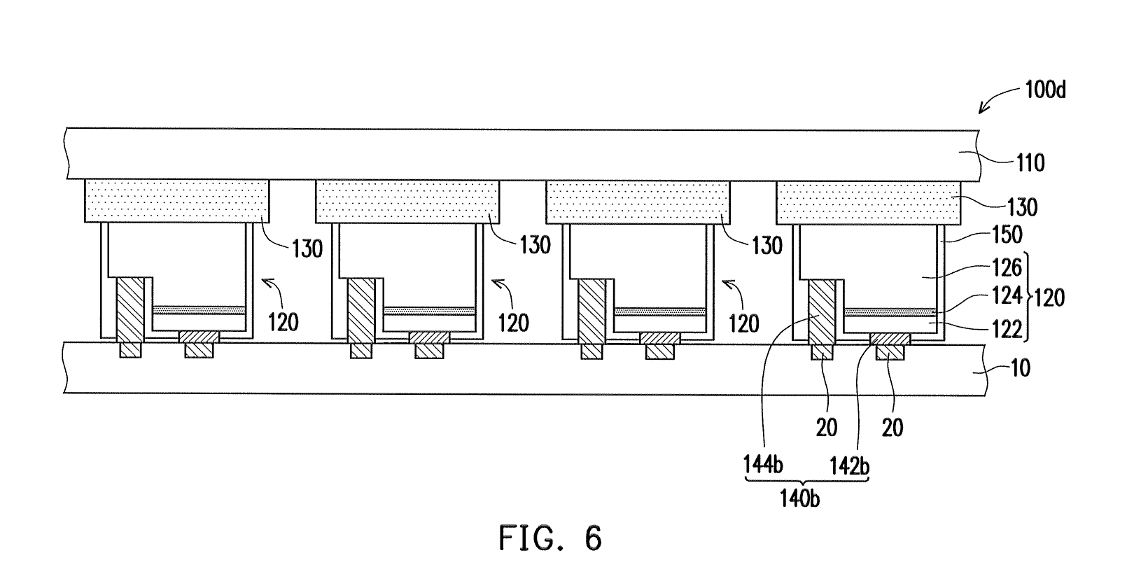

Besides, the light emitting device 100d may further include the insulating layer 150. The insulating layer 150 is disposed on the buffer pad 130 and covers the epitaxial structure 120, and the insulating layer 150 exposes the first bonding pad 142b and the second bonding pad 144b. The insulating layer 150 is disposed to protect the edge of the epitaxial structure 120, so as to prevent the epitaxial structure 120 from moisture and oxygen, and may effectively improve a product reliability of the light emitting device 100d. The material of the insulating layer 150 includes silicon dioxide, aluminum oxide, silicon nitride, and a combination thereof, for example. In the subsequent process, referring to FIG. 6, when the light emitting device 100d is electrically connected to the receiving substrate 10 through the thermal bonding process, the first bonding pad 142b and the second bonding pad 144b may be electrically connected to the pad 20 on the receiving substrate 10. For example, the receiving substrate may be a display substrate, a lighting substrate, a substrate having transistors or integrated circuits, or a substrate having metal redistribution lines. At this time, the buffer pad 130 may absorb the internal stress generated during bonding and reduce the movement generated when the high stress is applied to the epitaxial structure 120. In brief, the buffer pad 130 may prevent the dislocation between the epitaxial structure 120 and the receiving substrate 10. Thus, the structural design of the light emitting device 100d of this embodiment helps the subsequent thermal bonding process, and may effectively improve a structural reliability of the light emitting device 100d.

In view of the foregoing, since the light emitting device according to the embodiments of the invention has the buffer pad, the buffer pad may absorb the internal stress generated during bonding when the light emitting device is subsequently thermally bonded to the receiving substrate and reduce and the movement generated when a high stress is applied to the epitaxial structure. In brief, the buffer pad may prevent the dislocation between the epitaxial structure and the receiving substrate. Thus, the structural design of the light emitting device according to the embodiments of the invention helps the subsequent thermal bonding process, and may effectively improve the structural reliability of the light emitting device.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A light emitting device, comprising:
a carrier;
at least one epitaxial structure, disposed on the carrier and comprising:
a first type semiconductor layer;
a second type semiconductor layer; and
an active layer, located between the first type semiconductor layer and the second type semiconductor layer, wherein a thickness of the second type semiconductor layer is greater than a thickness of the first type semiconductor layer;
at least one buffer pad, disposed on a top surface of the carrier and between the carrier and the epitaxial structure, wherein the second type semiconductor layer directly contacts the buffer pad, the epitaxial structure is bonded to the carrier by the buffer pad, and a material of the buffer pad comprises a polymer, and the buffer pad exposes part of the top surface, wherein an area of an orthogonal projection of the second type semiconductor layer is different from of an area of an orthogonal projection of the buffer pad on the carrier; and
at least one bonding pad, disposed on the epitaxial structure and between the epitaxial structure and a receiving substrate, wherein the epitaxial structure is electrically connected to the receiving substrate through the bonding pad.

2. The light emitting device as claimed in claim 1, wherein the carrier is a tentative substrate.

3. (canceled)

4. The light emitting device as claimed in claim 1, wherein a side length of the first type semiconductor layer is smaller than a side length of the second type semiconductor layer, and a difference in side lengths between the first type semiconductor layer and the second type semiconductor layer is in a range from 0.5 micrometers to 5 micrometers.

5. (canceled)

6. The light emitting device as claimed in claim 1, wherein the thickness of the second type semiconductor layer is 3 times to 15 times of a thickness of the active layer, and the thickness of the second type semiconductor layer is 10 times to 20 times of the thickness of the first type semiconductor layer.

7. The light emitting device as claimed in claim 1, wherein the at least one bonding pad comprises at least one first bonding pad and at least one second bonding pad, the first bonding pad and the second bonding pad are located at the same side of the epitaxial structure, the first bonding pad is electrically connected to the first type semiconductor layer, and the second bonding pad is electrically connected to the second type semiconductor layer.

8. The light emitting device as claimed in claim 1, further comprising:
an insulating layer, disposed on the buffer pad and covering a sidewall of the epitaxial structure, wherein the insulating layer exposes a top surface of the epitaxial structure to form a contact opening, and the bonding pad is disposed on the contact opening and electrically connected to the epitaxial structure.

9. The light emitting device as claimed in claim 1, wherein an area ratio of the buffer pad to the epitaxial structure is R, and 0.6≦R<1 or 1<R≦1.2.

10. The light emitting device as claimed in claim 1, wherein in a vertical direction with respect to the carrier, the buffer pad and the epitaxial structure are conformal patterns.

11. (canceled)

12. The light emitting device as claimed in claim 1, wherein a highest peak current density of an external quantum efficiency curve of the epitaxial structure is lower than 2 A/cm².

13. The light emitting device as claimed in claim 1, wherein a defect density of the epitaxial structure is less than 5×10⁸/cm².

14. A light emitting device, comprising:
a carrier;
a plurality of epitaxial structures, disposed on a top surface of the carrier periodically and separately, wherein each of the epitaxial structures comprises:
a first type semiconductor layer;
a second type semiconductor layer; and
an active layer, located between the first type semiconductor layer and the second type semiconductor layer, wherein a thickness of the second type semiconductor layer is greater than a thickness of the first type semiconductor layer;
a plurality of buffer pads, disposed between the carrier and the epitaxial structures and respectively disposed in correspondence with the second type semiconductor layer of the epitaxial structures, wherein the epitaxial structures respectively and directly contact the buffer pads, the epitaxial structures are respectively bonded on the carrier by the buffer pads, the buffer pads expose part of the top surface of the carrier, and a material of the buffer pads comprises a polymer; and
a plurality of bonding pads, disposed on the epitaxial structures, wherein the epitaxial structures are electrically connected to a receiving substrate through the bonding pads, and a gap between any adjacent two of the buffer pads is 0.2 times to 2 times of a side length of each of the epitaxial structures.

15. The light emitting device as claimed in claim 1, wherein the epitaxial structure is temporarily bonded to the carrier by the buffer pad.

16. The light emitting device as claimed in claim 1, wherein the buffer pad is formed through thermal curing or UV curing.

17. The light emitting device as claimed in claim 14, wherein an area ratio of each of the buffer pads to each of the epitaxial structures is R, and 0.6≦R<1 or 1<R≦1.2.

18. The light emitting device as claimed in claim 14, wherein the bonding pads are disposed between the epitaxial structures and a receiving substrate.

19. The light emitting device as claimed in claim 14, wherein the epitaxial structures are temporarily bonded to the carrier by the buffer pads.
